(19) United States
(12) Patent Application Publication
(10) Pub. No.: US 2026/0096449 A1
(43) Pub. Date: Apr. 2, 2026

(54) PACKAGE STRUCTURE

(71) Applicant: Advanced Semiconductor Engineering, Inc., Kaohsiung (TW)

(72) Inventors: Ko-Pu WU, Taoyuan (TW); Chieh-Yin LIN, Taoyuan (TW); Chin Li HUANG, Taoyuan (TW); Chih-Hung HSU, New Taipei City (TW)

(73) Assignee: Advanced Semiconductor Engineering, Inc., Kaohsiung (TW)

(21) Appl. No.: 18/902,818

(22) Filed: Sep. 30, 2024

(51) Int. Cl. H01L 23/495; H01L 21/56; H01L 23/00; H01L 23/29; H01L 23/31; H01L 25/065

(52) U.S. Cl. CPC H10W 70/424; H10W 70/457; H10W 74/117; H10W 74/473; H10W 72/877; H10W 72/884; H10W 74/016; H10W 74/10; H10W 90/00; H10W 90/724; H10W 90/732; H10W 90/754

(57) ABSTRACT

A package structure is provided. The package structure includes a leadframe, an electronic component, an encapsulant, and a first reflowable material. The leadframe includes a first lead. The electronic component is disposed over and electrically connected to an upper surface of the leadframe. The encapsulant encapsulates the leadframe and defines a first opening exposing a first portion of a lower surface of the first lead. The first reflowable material is disposed in the first opening. The first opening is defined by curved surfaces of the encapsulant formed by etching the leadframe and has a cross-sectional profile tapering away from the first lead.

### BACKGROUND

### 1. Technical Field The present disclosure relates generally to a package structure.

### 2. Description of the Related Art

QFN (Quad Flat No-lead) is an encapsulated package using a leadframe. The leadframe may include a die paddle and a plurality of leads. The QFN package is a leadless surface mount package in which the leadframe is located at and exposed from the bottom of the package. Thus, a very compact size of the package and a minimum foot print area of a printed circuit board (PCB) may be obtained. However, the lower surfaces of the leads and the lower surface of the die paddle exposed from the bottom of the package are substantially flat, and thus solder connections cannot be fixedly attached to the lower surfaces of the leads and the lower surface of the die paddle.

### SUMMARY

In one or more arrangements, a package structure includes a leadframe, an electronic component, an encapsulant, and a first reflowable material. The leadframe includes a first lead. The electronic component is disposed over and electrically connected to an upper surface of the leadframe. The encapsulant encapsulates the leadframe and defines a first opening exposing a first portion of a lower surface of the first lead. The first reflowable material is disposed in the first opening. The first opening is defined by curved surfaces of the encapsulant formed by etching the leadframe and has a cross-sectional profile tapering away from the first lead.

In one or more arrangements, a package structure includes a leadframe, an encapsulant, a first reflowable material, and a second reflowable material. The leadframe includes a first lead. The encapsulant encapsulates the first lead and defines a first opening and a second opening partially exposing the first lead. The first reflowable material is disposed in the first opening and including a portion protruding out of the first opening by a protruding distance. The second reflowable material is disposed in the second opening. A difference between a height of the first reflowable material and a height of the second reflowable material is less than the protruding distance.

In one or more arrangements, a package structure includes a leadframe, an electronic component, an encapsulant, a first solder ball, and an insulating element. The leadframe has a first surface and a second surface opposite to the first surface. The electronic component is disposed over and electrically connected to the first surface of the leadframe. The encapsulant encapsulates the leadframe. The first solder ball is disposed over the second surface of the leadframe. The insulating element is configured to cover a portion of the second surface of the leadframe exposed by the encapsulant. A material of the insulating element is different from a material of the encapsulant.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a top view of a package structure in accordance with some arrangements of the present disclosure.

FIG. 1B is a cross-section of a package structure in accordance with some arrangements of the present disclosure.

FIG. 1C is a cross-section of a package structure in accordance with some arrangements of the present disclosure.

FIG. 1D is a cross-section of a package structure in accordance with some arrangements of the present disclosure.

FIG. 2A is a cross-section of a portion of a package structure in accordance with some arrangements of the present disclosure.

FIG. 2B is a cross-section of a portion of a package structure in accordance with some arrangements of the present disclosure.

FIG. 2C is a cross-section of a portion of a package structure in accordance with some arrangements of the present disclosure.

FIG. 3A is a perspective view of a portion of a package structure in accordance with some arrangements of the present disclosure.

FIG. 3B is a perspective view of a portion of a package structure in accordance with some arrangements of the present disclosure.

FIG. 4A to FIG. 4E illustrate various stages of an exemplary method of forming a package structure in accordance with some arrangements of the present disclosure.

FIG. 4F illustrates one or more stages of an exemplary method of forming a package structure in accordance with some arrangements of the present disclosure.

FIG. 5A to FIG. 5E illustrate various stages of an exemplary method of forming a package structure in accordance with some arrangements of the present disclosure.

FIG. 5F illustrates one or more stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

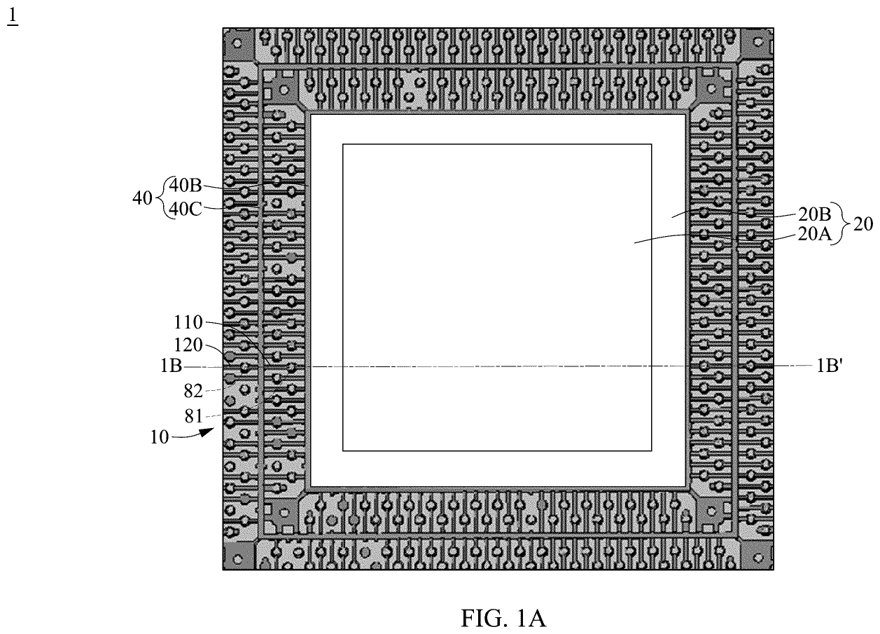

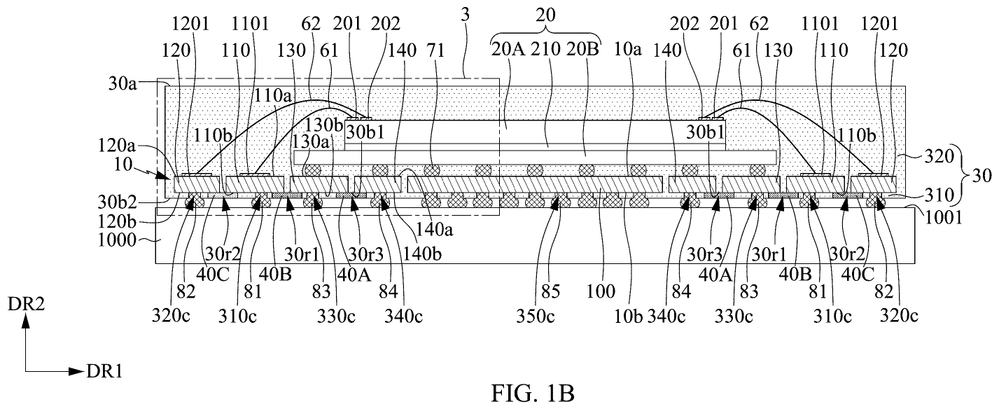

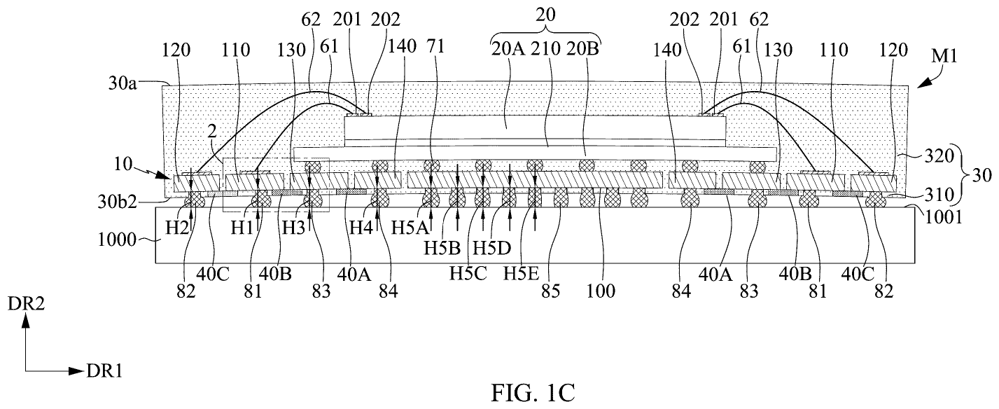

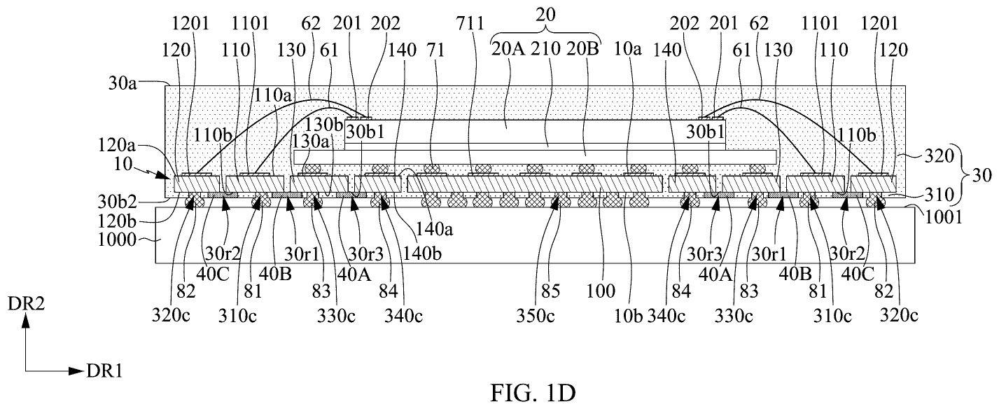

FIG. 1A is a top view of a package structure 1 in accordance with some arrangements of the present disclosure. FIG. 1B is a cross-section of a package structure 1 in accordance with some arrangements of the present disclosure. In some arrangements, FIG. 1B is a cross-section along a line 1B-1B′ in FIG. 1A. The package structure 1 may include a substrate 1000, a leadframe 10, an electronic component 20, an encapsulant 30, a connection structure 40, conductive wires 61 and 62, and electrical contacts 71, 81, 82, 83, 84, and 85.

The substrate 1000 may include, for example, a printed circuit board (PCB), such as a paper-based copper foil laminate, a composite copper foil laminate, or a polymer-impregnated glass-fiber-based copper foil laminate. The substrate 1000 may include an interconnection structure, such as a plurality of conductive traces and/or a plurality of conductive vias. In some arrangements, the substrate 1000 includes a ceramic material, a metal plate, or an organic substrate. In some arrangements, the substrate 1000 may include a two-layer substrate which includes a core layer and a conductive material and/or structure disposed on an upper surface and a bottom surface of the substrate 1000. The conductive material and/or structure may include a plurality of conductive traces.

The leadframe 10 may be disposed over and electrically connected to the substrate 1000. The leadframe 10 may include a surface 10a (or an upper surface) and a surface 10b (or a lower surface) opposite to the surface 10a. In some arrangements, the leadframe 10 includes a die paddle 100 and leads 110, 120, 130, and 140. In some arrangements, the leads 110, 120, 130, and 140 are spaced apart from one another. In some arrangements, upper surfaces 110a, 120a, 130a, and 140a of the leads 110, 120, 130, and 140 face the electronic component 20, and lower surfaces 110b, 120b, 130b, and 140b face the substrate 1000. In some arrangements, the leadframe 10 may be formed or include a metal material, e.g., copper (Cu), copper alloy, iron/iron (Fe) alloy, nickel/nickel (Ni) alloy, or any other metal/metal alloy. In some arrangements, the leadframe 10 may be coated with silver (Ag) layers. In some arrangements, Ag layers 1101 and 1201 are coated on upper surfaces 110a and 120a of the leads 110 and 120, respectively.

In some arrangements, referring to FIG. 1A, the leads 110 and 120 may extend along various directions. In some arrangements, the leads 110 and 120 extend outward in a radial pattern from around the electronic component 20. In some arrangements, the leads 110 may be connected to the leads 120 through an insulating connector structure (e.g., the connection structure 40). The leads 110, 120, 130, and 140 may extend outward in a radial pattern from around the die paddle 100. Compared to a leadframe with a die paddle surrounded by only one row of leads, the die paddle 100 is surrounded by multiple rows of leads 110, 120, 130, and 140, thereby providing more I/O terminals.

The electronic component 20 may be disposed over and electrically connected to the leadframe 10. In some arrangements, the electronic component 20 is disposed over and electrically connected to an upper surface (e.g., the surface 10a) of the leadframe 10. In some arrangements, the electronic component 20 includes a chip 20B (or a die), a chip 20A (or a die) stacked over the chip 20B, and an adhesive layer 210 connecting the chip 20A to the chip 20B. The chips 20A and 20B may independently include a semiconductor substrate, one or more integrated circuit devices and one or more overlying interconnection structures therein. The integrated circuit devices may include active devices such as transistors and/or passive devices such resistors, capacitors, inductors, or a combination thereof. The chips 20A and 20B may independently include an active component, such as an integrated circuit (IC) chip or a die, a passive electrical component, such as a capacitor, a resistor or an inductor, or a combination thereof. The electronic component 20 may further include a plurality of conductive pads (e.g., conductive pads 201 and 202). The multiple conductive pads may be configured to electrically connect to the multiple leads of the leadframe 10.

The encapsulant 30 may be disposed over the substrate 1000. In some arrangements, the encapsulant 30 encapsulates the leadframe 10 and the electronic component 20. In some arrangements, the encapsulant 30 includes a portion 310 contacting the surface 10b of the leadframe 10 and a portion 320 contacting the electronic component 20. The portions 310 and 320 may collectively form a monolithic or single-piece encapsulant structure (i.e., the encapsulant 30). In some arrangements, the encapsulant 30 has an upper surface 30a and lower surfaces 30b1 and 30b2 facing away from the leadframe 10. In some arrangements, the lower surfaces 30b1 and 30b2 are at different elevations. The encapsulant 30 may include an epoxy resin having fillers dispersed therein, a molding compound (e.g., an epoxy molding compound or other molding compound), polyimide (PI), a phenolic compound or material, a polymer material with silicone dispersed therein, or a combination thereof.

In some arrangements, the encapsulant 30 defines a plurality of openings that expose portions of the surface 10b of the leadframe 10. In some arrangements, the portion 310 of the encapsulant 30 defines openings 310c, 320c, 330c, 340c, 350c, 30r1, 30r2, and 30r3 (also referred to as “recesses”). In some arrangements, the openings 310c, 320c, 330c, 340c, 350c, 30r1, 30r2, and 30r3 (or the recesses) are spaced apart from one another. In some arrangements, the opening 310c exposes a portion (or a first portion) of a lower surface 110b of the lead 110. In some arrangements, each of the openings 320c, 330c, 340c, and 350c exposes a portion (or a first portion) of a lower surface of each of the leads 120, 130, and 140, and a portion of a lower surface of the die paddle 100. In some arrangements, the opening 30r1 (or the recess) exposes a portion (or a second portion) of the lower surface 110b of the lead 110. In some arrangements, the opening 30r1 (or the recess) exposes a portion (or a second portion) of the lower surface 130b of the lead 130. In some arrangements, the opening 30r1 (or the recess) exposes a portion of the lower surface 30b1 of the encapsulant 30. In some arrangements, the opening 30r2 (or the recess) exposes a portion (or a second portion) of the lower surface 110b of the lead 110, a portion (or a second portion) of the lower surface 120b of the lead 120, and a portion of the lower surface 30b1 of the encapsulant 30. In some arrangements, the opening 30r3 (or the recess) exposes a portion (or a second portion) of the lower surface 130b of the lead 130, a portion (or a second portion) of the lower surface 140b of the lead 140, and a portion of the lower surface 30b1 of the encapsulant 30.

The connection structure 40 may be connected to the leads 110, 120, 130, and 140 of the leadframe 10. The connection structure 40 may be formed of or include an insulating material. In some arrangements, the connection structure 40 includes insulating elements 40A, 40B, and 40C. The insulating element (e.g., the insulating elements 40A, 40B, and 40C) is configured to cover a portion of the surface 10b of the leadframe 10 exposed by the encapsulant 30. In some arrangements, a material of the insulating element is different from a material of the encapsulant 30. The connection structure 40 may be configured to connect the 110, 120, 130, and 140 without electrically connecting the 110, 120, 130, and 140 to one another. In some arrangements, the insulating element 40A is disposed in the opening 30r3 and has a surface 40b concave toward the inner portion of the insulating element 40A. In some arrangements, the insulating element 40B is disposed in the opening 30r1 and has a surface 40b concave toward the inner portion of the insulating element 40B. In some arrangements, the insulating element 40C is disposed in the opening 30r2 and has a surface 40b concave toward the inner portion of the insulating element 40C. The insulating elements 40A, 40B, and 40C may include an insulating material, e.g., solder mask, solder resist, or any suitable dielectric material.

In some arrangements, referring to FIG. 1A, the insulating element 40B substantially surrounds the electronic component 20 and connect the leads 110. In some arrangements, referring to FIG. 1A, the insulating element 40C substantially surrounds the electronic component 20 and connect the leads 110 and the leads 120. In some arrangements, referring to FIG. 1A, the insulating element 40C substantially surrounds the insulating element 40B. In some arrangements, referring to FIG. 1A and FIG. 1B, the opening 30r1 for the insulating element 40B extends across the lower surfaces of the leads 110 and exposes portions of the lower surfaces of the leads 110. In some arrangements, referring to FIG. 1A and FIG. 1B, the opening 30r2 for the insulating element 40C extends across the lower surfaces of the leads 110 and 120 and exposes portions of the lower surfaces of the leads 110 and 120.

The conductive wires 61 and 62 may electrically connect the electronic component 20 to the surface 10a of the leadframe 10. In some arrangements, the conductive wire 61 electrically connects the conductive pad 201 to the Ag layer 1101 on the lead 110. In some arrangements, the conductive wire 62 electrically connects the conductive pad 202 to the Ag layer 1201 on the lead 120. The conductive wires 61 and 62 may be or include bonding wires. The package structure 1 may include additional conductive wires for electrically connecting the electronic component 20 to various leads of the leadframe 10. The number of the conductive wires may vary according to actual application.

The electrical contacts 71 may be disposed between the electronic component 20 and the leadframe 10. In some arrangements, the electrical contacts 71 electrically connect the electronic component 20 to the surface 10a of the leadframe 10. The electrical contact 71 may include a solder material. The electrical contact 71 may be referred to as a solder element. In some arrangements, the electrical contacts 71 include controlled collapse chip connection (C4) bumps, a ball grid array (BGA), or a land grid array (LGA).

The electrical contacts 81, 82, 83, 84, and 85 may be disposed over and electrically connected to the surface 10b of the leadframe 10. In some arrangements, the electrical contacts 81, 82, 83, 84, and 85 partially overlaps the encapsulant 30 and the insulating element (e.g., the insulating elements 40A, 40B, and 40C) in a direction DR1 substantially parallel to the surface 10b. In some arrangements, the electrical contacts 81, 82, 83, 84, and 85 contact portions of the lower surface 30b2 of the encapsulant 30. In some arrangements, the portion 310 of the encapsulant 30 contacts the surface 10b of the leadframe 10 and overlaps the electrical contacts 81, 82, 83, 84, and 85 in the direction DR1. The electrical contacts 81, 82, 83, 84, and 85 may be or include one or more reflowable materials. The electrical contacts 81, 82, 83, 84, and 85 may include one or more solder materials. The electrical contacts 81, 82, 83, 84, and 85 may be referred to as solder elements. In some arrangements, the electrical contacts 81, 82, 83, 84, and 85 include C4 bumps, a BGA, or a LGA. In some arrangements, a total number of the electrical contacts 81, 82, 83, 84, and 85 is greater than a number of the electrical contacts 71.

In some arrangements, the portion 310 of the encapsulant 30 defines openings 310c, 320c, 330c, 340c, and 350c for accommodating portions of the electrical contacts 81, 82, 83, 84, and 85. In some arrangements, the electrical contacts 81, 82, 83, 84, and 85 are at least partially disposed in the openings 310c, 320c, 330c, 340c, and 350c, respectively. In some arrangements, the electrical contacts 81, 82, 83, 84, and 85 partially protrude beyond the encapsulant 30. In some arrangements, each of the electrical contacts 81, 82, 83, 84, and 85 partially protrudes beyond the encapsulant 30.

In some arrangements, one or more of the electrical contacts 81, 82, 83, 84, and 85 may have a stepped portion contacting the encapsulant 30. In some arrangements, one or more of the electrical contacts 81, 82, 83, 84, and 85 may include a curved portion extending into the leadframe 10. In some arrangements, each of the electrical contacts 81, 82, 83, 84, and 85 includes a curved portion extending into the leads 110, 120, 130, and 140, and the die paddle 100.

In some arrangements, the insulating element 40B is disposed in the opening 30r1 and overlapping at least one of the electrical contacts 81, 82, 83, 84, and 85 in the direction DR1. In some arrangements, the insulating element 40A is disposed in the opening 30r3 and overlapping at least one of the electrical contacts 81, 82, 83, 84, and 85 in the direction DR1. In some arrangements, the insulating element 40C is disposed in the opening 30r2 and overlapping at least one of the electrical contacts 81, 82, 83, 84, and 85 in the direction DR1.

In some arrangements, the electronic component 20 is free from overlapping the electrical contacts 81 and 82 (or the solder elements) in a direction DR2 which is substantially perpendicular to the direction DR1. In some arrangements, the electronic component 20 overlaps the electrical contacts 83, 84, and 85 (or the solder elements) in the direction DR2. In some arrangements, the conductive wire 61 (or the bonding wire) is electrically connected to the electrical contact 81 through the leadframe 10. In some arrangements, the conductive wire 62 (or the bonding wire) is electrically connected to the electrical contact 82 through the leadframe 10.

Currently, a QFN package may achieve electrical connection through leads, and exposed surfaces of the leads of the QFN are substantially planar with the outer surfaces of the QFN structure. As a result, the leads can only be electrically connected to an external substrate (e.g., a PCB) through plated tin layers. In contrast, according to some arrangements of the present disclosure, the encapsulant 30 defines the openings 310c, 320c, 330c, 340c, and 350c below the lower surface 10b of the leadframe 10 for accommodating the electrical contacts 81, 82, 83, 84, and 85 (e.g., solder elements or solder balls). Therefore, solder balls can be used for electrically connecting a QFN package to an external substrate (e.g., a PCB).

In addition, according to some arrangements of the present disclosure, the encapsulant 30 can serve to encapsulate the leadframe 10 and the electronic component 20 and also define openings to expose terminals of the leadframe 10. Therefore, operations of forming an additional dielectric layer (e.g., a solder mask or a solder resist) on the lower surface of the leadframe 10 and defining openings penetrating the additional dielectric layer can be omitted. Accordingly, the process can be simplified, and the costs can be reduced.

Furthermore, according to some arrangements of the present disclosure, the openings 310c, 320c, 330c, 340c, and 350c for solder balls and the openings 30r1, 30r2, and 30r3 for insulating connectors can be formed by one etching operation. Therefore, the process is further simplified, and the cost is reduced significantly. For example, compared to a BGA package structure, the cost for manufacturing the QFN package structure including solder balls can be reduced by 30% to 50%.

Moreover, according to some arrangements of the present disclosure, the die paddle 100 is arranged with multiple rows of leads 110, 120, 130, and 140 which are connected to one another through insulating connectors (e.g., the insulating elements 40A, 40B, and 40C). Therefore, the package structure 1 may be or include a QFN package structure with the leadframe 10 providing an increased number of I/O terminals, and the encapsulant 30 further defines openings in which solder balls can be disposed to electrically connect to the I/O terminals. Accordingly, the QFN package and the solder balls are provided with advantages of low manufacturing costs, and the design of the leadframe 10 and the encapsulant 30 with the openings are further provided with advantages of increasing the number of I/O terminals significantly. For example, for the package structure 1 having a size of about 15 mm*15 mm, the I/O terminals provided can be up to greater than 400.

FIG. 1C is a cross-section of a package structure 1C in accordance with some arrangements of the present disclosure. In some arrangements, FIG. 1C shows a cross-section along a line 1B-1B′ in FIG. 1A. The package structure 1C illustrated in FIG. 1C is similar to the package structure 1 illustrated in FIG. 1B, and the differences therebetween are described as follows.

In some arrangements, the package structure 1C includes a molded structure M1 connected or bonded to the substrate 1000 through the electrical contacts 81, 82, 83, 84, and 85. In some arrangements, the molded structure M1 includes the leadframe 10, the electronic component 20, the encapsulant 30, the conductive wires 61 and 62, and the electrical contacts 71. In some arrangements, the molded structure M1 includes a curve structure. In some arrangements, an upper surface (e.g., the upper surface 30a) and the lower surface (e.g., the surface 30b2) include curved surfaces. In some arrangements, the lower surface of the molded structure M1 is concave toward an inner portion of the molded structure M1. In some arrangements, a distance between an upper surface 1001 of the substrate 1000 and the lower surface (e.g., the surface 30b2) of the molded structure M1 vary from an edge toward a center portion of the molded structure M1. In some arrangements, a distance between the upper surface 1001 of the substrate 1000 and the lower surface (e.g., the surface 30b2) of the molded structure M1 increases from an edge toward a center portion of the molded structure M1. In some arrangements, a greater distance between the upper surface 1001 of the substrate 1000 and the lower surface (e.g., the surface 30b2) of the molded structure M1 results in a relatively large gap between the substrate 1000 and the molded structure M1, and a smaller distance between the upper surface 1001 of the substrate 1000 and the lower surface (e.g., the surface 30b2) of the molded structure M1 results in a relatively small gap between the substrate 1000 and the molded structure M1.

In some arrangements, the non-uniform distance between the upper surface 1001 of the substrate 1000 and the lower surface (e.g., the surface 30b2) of the molded structure M1 may be resulted from a warpage of the molded structure M1. When the amount of the solder material for each electrical contact is approximately the same, the electrical contact located in a larger gap between the molded structure M1 and the substrate 1000 may be stretched, resulting in formation of the electrical contact having a greater height and a smaller width. Conversely, the electrical contact located in a smaller gap will be compressed, resulting formation of the electrical contact having a smaller height and a greater width.

In some arrangements, the electrical contacts 81, 82, 83, 84, and 85 have different thicknesses (or heights). In some arrangements, the electrical contacts 85 have different heights H5A, H5B, H5C, H5D, and H5E. The height H5E is greater than the height H5D, the height H5D is greater than the height H5C, the height H5C is greater than the height H5B, and the height H5B is greater than the height H5A. In some arrangements, the height H5A of the electrical contact 85 is greater than the height H4 of the electrical contact 84, the height H4 of the electrical contact 84 is greater than the height H3 of the electrical contact 83, the height H3 of the electrical contact 83 is greater than the height H2 of the electrical contact 82, and the height H2 of the electrical contact 82 is greater than the height H1 of the electrical contact 81.

In some arrangements, the electrical contacts 81, 82, 83, 84, and 85 have different widths. In some arrangements, the electrical contacts 85 have different various widths. The widths increase from a center one (e.g., the one with the height H5E) toward an edge one (e.g., the one with the height 5A) of the electrical contacts 85. In some arrangements, the width of the electrical contact 85 is less than the width of the electrical contact 84, the width of the electrical contact 84 is less than the width of the electrical contact 83, the width of the electrical contact 83 is less than the width of the electrical contact 82, and the width of the electrical contact 82 is less than the width of the electrical contact 81.

According to some arrangements of the present disclosure, the electrical contacts formed of or including solder materials can provide tolerance for the distance variation between the molded structure M1 and the substrate 1000 resulted from the warpage of the molded structure M1. Therefore, electrical contacts can connect or bond to the molded structure M1 and the substrate 1000 nicely without delamination. Accordingly, the yield of the package structure can be increased, and the reliability of the package structure can be increased as well. For example, for the package structure 1 having a size of about 15 mm*15 mm, the I/O terminals provided can be up to greater than 400, and the board-level reliability (BLR) can be increased by 20% or higher.

FIG. 1D is a cross-section of a package structure 1D in accordance with some arrangements of the present disclosure. In some arrangements, FIG. 1D shows a cross-section along a line 1B-1B′ in FIG. 1A. The package structure 1D illustrated in FIG. 1D is similar to the package structure 1 illustrated in FIG. 1B, and the differences therebetween are described as follows.

In some arrangements, the package structure 1D further includes Ag layers 711 between the leadframe 10 and the electrical contacts 71.

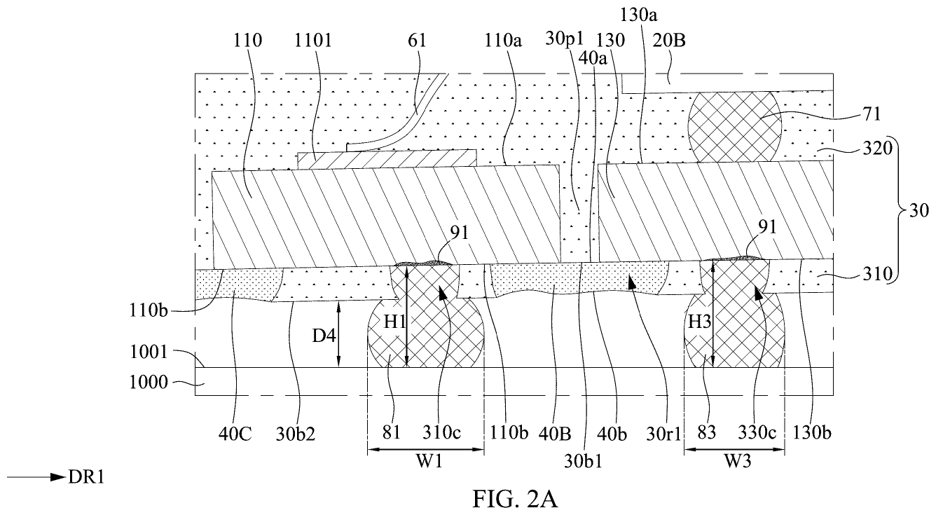

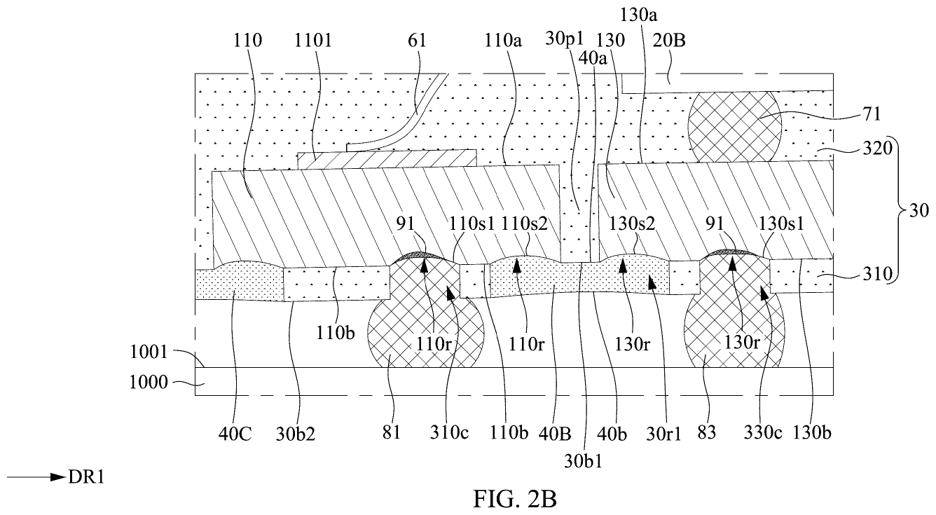

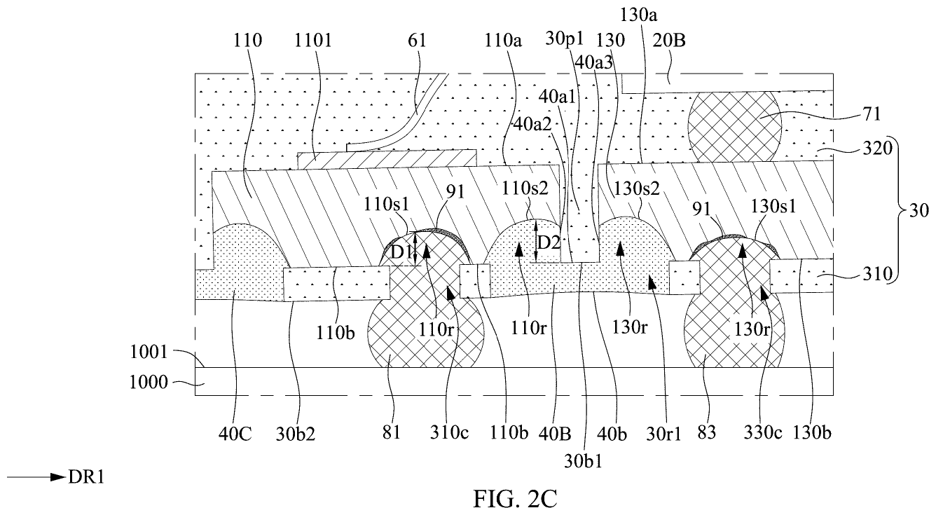

FIG. 2A is a cross-section of a portion of a package structure in accordance with some arrangements of the present disclosure. In some arrangements, FIG. 2A is a cross-section of a portion 2 of the package structure 1C in FIG. 1C.

In some arrangements, referring to FIG. 1C and FIG. 2A, the substrate 1000 is electrically connected to the leadframe 10 through the electrical contacts 81, 82, 83, 84, and 85. In some arrangements, a thickness (e.g., a height H1) of the electrical contact 81 is different from a thickness (e.g., a height H3) of the electrical contact 83. In some arrangements, a thickness (e.g., a height H1) of the electrical contact 81 (or the solder element) is less than a thickness (e.g., a height H3) of the electrical contact 83 (or the solder element). In some arrangements, a distance between the height H1 of the electrical contact 81 and the height H3 of the electrical contact 83 is less than a distance D4 between the upper surface 1001 of the substrate 1000 and the lower surface (e.g., the surface 30b2) of the encapsulant 30. In some arrangements, the electrical contact 81 includes a portion protruding out of the opening 310c by the distance D4. In some arrangements, a width W1 of the electrical contact 81 is different from a width W3 of the electrical contact 83. In some arrangements, a width W1 of the electrical contact 81 is greater than a width W3 of the electrical contact 83.

In some arrangements, the package structure 1C includes an intermetallic compound (IMC) layer 91 between the electrical contact 81 and the lead 110. In some arrangements, the IMC layer 91 has a non-uniform thickness and directly contacts the electrical contact 81 and the lead 110. The insulating element 40B may have a substantially planar upper surface 40a and a concave lower surface (e.g., the surface 40b). In some arrangements, the surface 40b of the insulating element 40B is concave toward an inner portion of the insulating element 40B. In some arrangements, the insulating element 40B has opposite lateral sides (or lateral surfaces) both connected to the encapsulant 30, and the surface 40b of the insulating element 40B includes a first concave portion and a second concave portion concave toward the inner portion by different depths.

In some arrangements, the opening 310c may be formed by removing a portion of the leadframe 10 by etching. In some arrangements, the opening 310c is defined by curved surfaces of the encapsulant 30 formed by etching the leadframe 10 and having a cross-sectional profile tapering away from the lead 110. In some arrangements, the opening 330c may be formed by removing a portion of the leadframe 10 by etching. In some arrangements, the opening 330c is defined by curved surfaces of the encapsulant 30 formed by etching the leadframe 10 and having a cross-sectional profile tapering away from the lead 110. In some arrangements, the opening 30r1 may be formed by removing a portion of the leadframe 10 by etching. In some arrangements, the opening 30r1 is defined by curved surfaces of the encapsulant 30 formed by etching the leadframe 10 and having a cross-sectional profile tapering away from the lead 110.

FIG. 2B is a cross-section of a portion of a package structure in accordance with some arrangements of the present disclosure. In some arrangements, FIG. 2B is a cross-section of a portion 2 of the package structure 1C in FIG. 1C.

In some arrangements, referring to FIG. 1C and FIG. 2B, the opening 310c partially exposes the lead 110, the opening 320c partially exposes the lead 120, the opening 330c partially exposes the lead 130, the opening 340c partially exposes the lead 140, and the opening 350c partially exposes the die paddle 100.

In some arrangements, the electrical contact 81 (or the solder element) is disposed in the opening 310c and partially extends into the lead 110. In some arrangements, the electrical contact 81 (or the solder element) and the lead 110 define a curved interface 110s1 convex toward the lead 110. In some arrangements, the electrical contact 81 and a recess 110r of the lead 110 define the curved interface 110s1. In some arrangements, the curved interface 110s1 is free from overlapping the encapsulant 30 in the direction DR1. In some arrangements, the IMC layer 91 contacts the curved interface 110s1. In some arrangements, the insulating element 40B and the lead 110 define a curved interface 110s2 convex toward the lead 110. In some arrangements, the electrical contact 81 and another recess 110r of the lead 110 define the curved interface 110s2.

In some arrangements, the lead 130 is spaced apart from the lead 110. In some arrangements, the electrical contact 83 (or the solder element) is disposed in the opening 330c and partially extends into the lead 130. In some arrangements, the electrical contact 83 (or the solder element) and the lead 130 define a curved interface 130s1 convex toward the lead 130. In some arrangements, the electrical contact 83 and a recess 130r of the lead 130 define the curved interface 130s1. In some arrangements, the curved interface 130s1 is free from overlapping the encapsulant 30 in the direction DR1. In some arrangements, the IMC layer 91 contacts the curved interface 130s1. In some arrangements, the insulating element 40B and the lead 130 define a curved interface 130s2 convex toward the lead 130. In some arrangements, the electrical contact 83 and another recess 110r of the lead 130 define the curved interface 130s2.

In some arrangements, the opening 30r1 is between the opening 310c and the opening 330c. In some arrangements, the encapsulant 30 includes a protrusion 30p1 extending into the opening 30r1. The protrusion 30p1 may have the lower surface 30b1. In some arrangements, the insulating element 40B is disposed in the opening 30r1 and contacting the protrusion 30p1 of the encapsulant 30. The insulating element 40B may have a non-planar upper surface 40a and a concave lower surface (e.g., the surface 40b). In some arrangements, the upper surface 40a includes a substantially planar portion (e.g., the lower surface 30b1) and curved portions (e.g., the interfaces 110s2 and 130s2). In some arrangements, a contact surface between the insulating element 40B and the leadframe 10 includes a wavy surface (e.g., a wavy surface including the interfaces 110s2 and 130s2 and the surface 30b2).

FIG. 2C is a cross-section of a portion of a package structure in accordance with some arrangements of the present disclosure. In some arrangements, FIG. 2C is a cross-section of a portion 2 of the package structure 1C in FIG. 1C.

In some arrangements, a portion of the electrical contact 81 (or the solder element) is between the lead 110 and the encapsulant 30. In some arrangements, a portion of the electrical contact 83 (or the solder element) is between the lead 130 and the encapsulant 30.

In some arrangements, the electrical contact 81 extends into the lead 110 by a distance D1, and the insulating element 40B extends into the lead 110 by a distance D2 different from the distance D1. In some arrangements, a width of the opening 30r1 is greater than a width of the opening 310c and a width of the opening 330c, and the distance D2 is greater than the distance D1. In some arrangements, a difference between the thickness of the lead 110 and the distance D1 is equal to or greater than about 10 μm. In some arrangements, a difference between the thickness of the lead 130 and the distance D3 is equal to or greater than about 10 μm. The insulating element 40B may have a recess for accommodating the protrusion 30p1 and a concave lower surface (e.g., the surface 40b). In some arrangements, the insulating element 40B has an upper surface 40a1 and lateral surfaces 40a2 and 40a3 defining the recess.

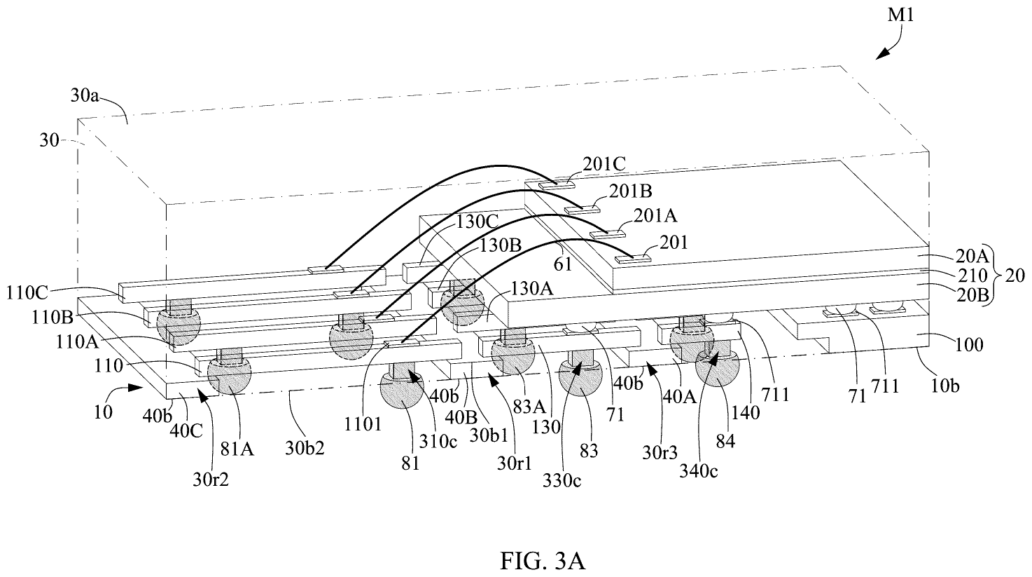

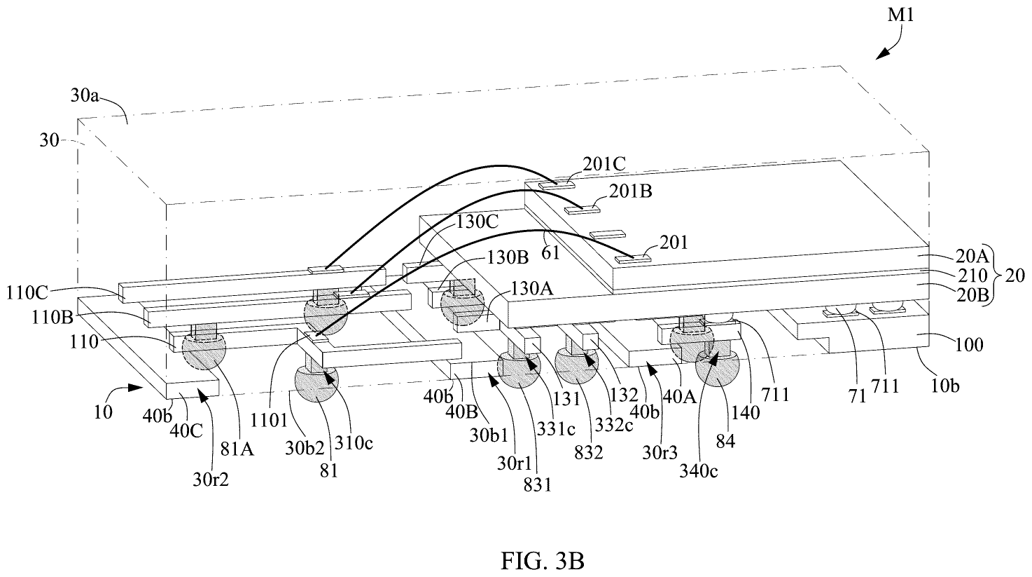

FIG. 3A is a perspective view of a portion of a package structure in accordance with some arrangements of the present disclosure. In some arrangements, FIG. 3A is a perspective view of a portion 3 of the package structure 1, the package structure 1C, or the package structure 1D in accordance with some arrangements of the present disclosure.

In some arrangements, the leadframe 10 includes leads 110, 110A, 110B, and 110C arranged in parallel and connected to the insulating elements 40B and 40C. In some arrangements, the leadframe 10 further includes leads 130, 130A, 130B, and 130C arranged in parallel. In some arrangements, the leads 110, 110A, 110B, and 110C and the leads 130, 130A, 130B, and 130C are connected to the insulating element 40B. In some arrangements, the leads 130, 130A, 130B, and 130C and the leads 140 are connected to the insulating element 40A.

In some arrangements, the electronic component 20 includes conductive pads 201, 201A, 201B, and 201C. In some arrangements, the chip 20A is electrically connected to the conductive wires 61 through the conductive pads 201, 201A, 201B, and 201C. In some arrangements, the conductive pad 201 is electrically connected to the lead 110 through the conductive wire 61, and the conductive wire 61 is electrically connected to the electrical contact 81 through the Ag layer 1101 and the lead 110. In some arrangements, the conductive pad 201A is electrically connected to the electrical contact 81A through the conductive wire 61, the lead 110A, and the Ag layer over the lead 110A. In some arrangements, the conductive pad 201B is electrically connected to the lead 110B through the conductive wire 61, and the conductive pad 201C is electrically connected to the lead 110C through the conductive wire 61. The leads 110, 110A, 110B, and 110C and the leads 130, 130A, 130B, and 130C are connected to and electrically isolated from each other by the insulating element 40B, and thus the multiple leads may serve as an array of I/O terminals of the leadframe 10. Therefore, the number of I/O terminals provided by the leadframe 10 can be increased significantly.

In some arrangements, the chip 20B is electrically connected to the leadframe 10 through the electrical contacts 71. In some arrangements, the chip 20B is electrically connected to the electrical contact 83 through the lead 130, and the chip 20B is electrically connected to the electrical contact 83A through the lead 130A.

FIG. 3B is a perspective view of a portion of a package structure in accordance with some arrangements of the present disclosure. In some arrangements, FIG. 3B is a perspective view of a portion of the package structure 1, the package structure 1C, or the package structure 1D in accordance with some arrangements of the present disclosure. The structure illustrated in FIG. 3B is similar to the structure illustrated in FIG. 3A, and the differences therebetween are described as follows.

In some arrangements, the lead 110 includes segments that extend in parallel to the lead 110B and a segment extending perpendicular to the lead 110B. In some arrangements, the leadframe 10 includes leads 131 and 132 arranged in parallel to each other and connected to the lead 130A. In some arrangements, the leads 131 and 132 extend substantially perpendicular to the lead 130A and the leads 110B and 110C.

In some arrangements, the conductive pad 201 is electrically connected to the lead 110 through the conductive wire 61, and the conductive wire 61 is electrically connected to the electrical contact 81 through the Ag layer 1101 and the lead 110. In some arrangements, the encapsulant 30 defines an opening 331c for accommodating a portion of the electrical contact 831 and an opening 332c for accommodating a portion of the electrical contact 832. In some arrangements, the chip 20B is electrically connected to the electrical contact 831 through the lead 131, and the chip 20B is electrically connected to the electrical contact 832 through the lead 132.

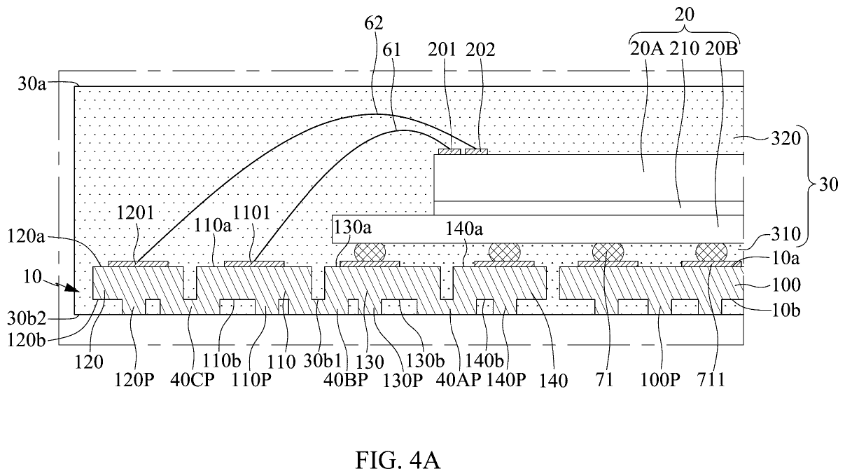

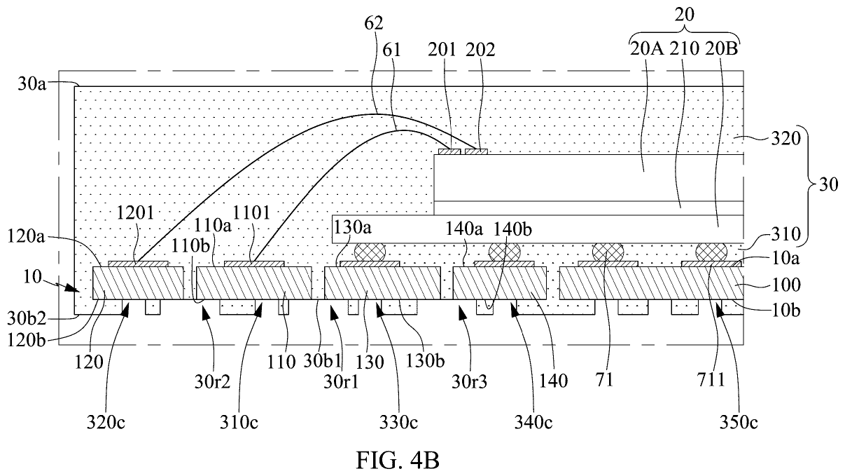

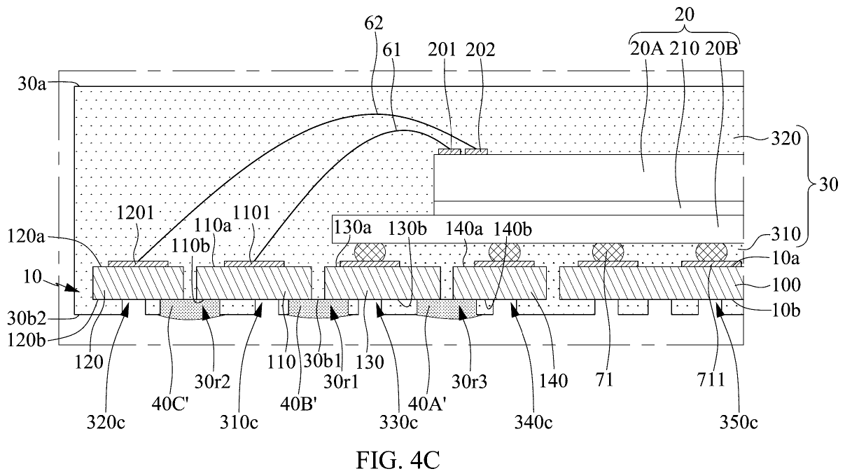

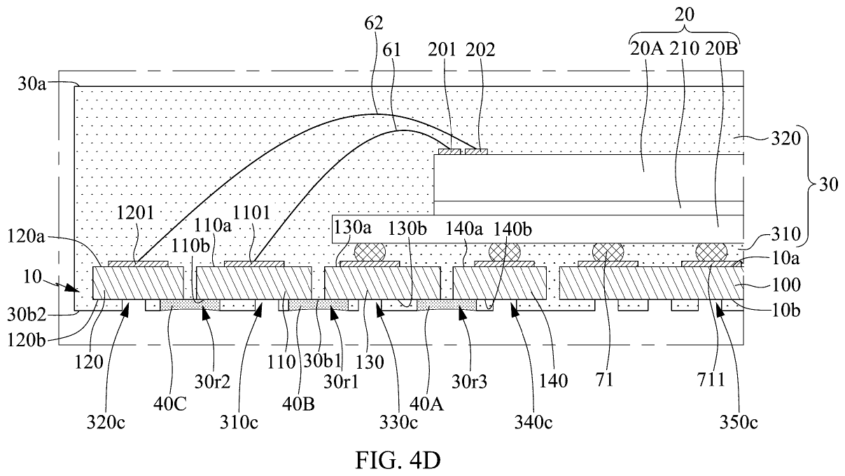

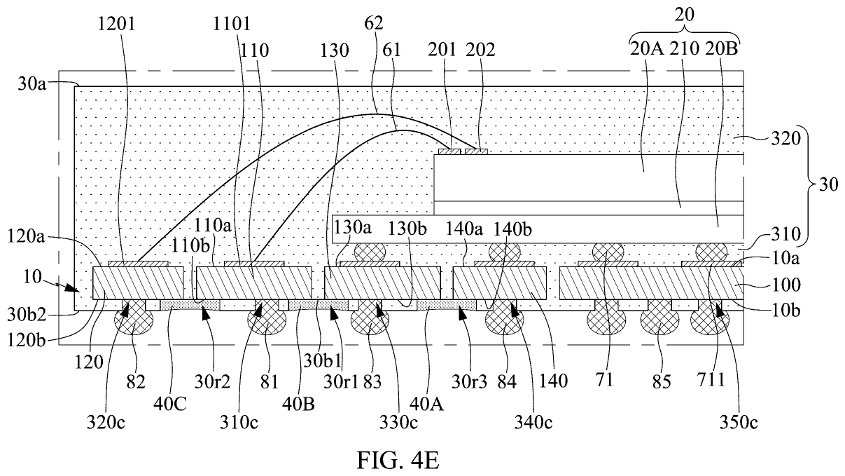

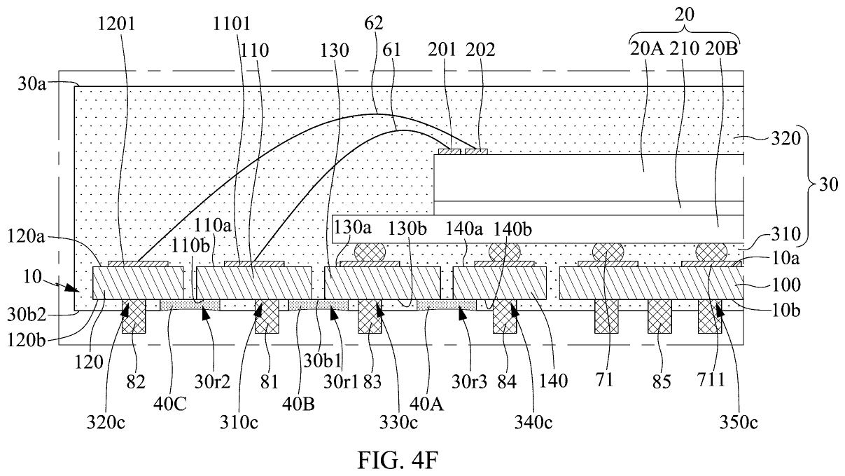

FIG. 4A to FIG. 4E illustrate various stages of an exemplary method of forming a package structure 1D in accordance with some arrangements of the present disclosure. In some arrangements, FIG. 4A to FIG. 4E show portions of intermediate structures at various stages of an exemplary method of forming a package structure 1D in accordance with some arrangements of the present disclosure.

Referring to FIG. 4A, a leadframe 10 including a die paddle 100, leads 110, 120, 130, and 140, conductive protrusions 100P, 110P, 120P, 130P, and 140P, and connectors 40AP, 40BP, and 40CP may be provided or formed. In some arrangements, the leadframe 10 is a single piece. In some arrangements, a whole metal plate is provided, and one or more connectors are formed through half-etching from above, such as the connectors 40AP, 40BP, and 40CP. Additionally, one or more leads and conductive protrusions are formed through half-etching from below, such as the leads 110, 120, 130, and 140 and the conductive protrusions 100P, 110P, 120P, 130P, and 140P. In some arrangements, an electronic component 20 including chips 20A and 20B and an adhesive layer 210B is connected to the leadframe 10 through electrical contacts 71, conductive wires 61 and 62 are provided to electrically connect the electronic component 20 to the leadframe 10, and an encapsulant 30 is provided to encapsulate the leadframe 10 and the electronic component 20.

Referring to FIG. 4B, the conductive protrusions 100P, 110P, 120P, 130P, and 140P and the connectors 40AP, 40BP, and 40CP may be removed by etching to form openings 310c, 320c, 330c, 340c, 350c, 30r1, 30r2, and 30r3.

Referring to FIG. 4C, insulating elements 40A′, 40B′ and 40C′ may be formed in the openings 30r1, 30r2, and 30r3, respectively. In some arrangements, the insulating elements 40A′, 40B′ and 40C′ partially protrude beyond the openings 30r1, 30r2, and 30r3 and partially cover the lower surface 30b2 of the encapsulant 30. In some arrangements, the insulating elements 40A′, 40B′ and 40C′ are formed by coating.

Referring to FIG. 4D, exposed surfaces of the insulating elements 40A′, 40B′ and 40C′ may be partially removed to form insulating elements 40A, 40B, and 40C having exposed surfaces that are not protruding beyond the lower surface 30b2 of the encapsulant 30. The exposed surfaces of the insulating elements 40A′, 40B′ and 40C′ may be partially removed by polishing.

Referring to FIG. 4E, electrical contacts 81, 82, 83, 84, and 85 may be disposed in the openings 310c, 320c, 330c, 340c, and 350c. The electrical contacts 81, 82, 83, 84, and 85 may include solder elements, e.g., solder balls. Next, the structure illustrated in FIG. 4E may be connected to a substrate 1000 through the electrical contacts 81, 82, 83, 84, and 85 to form the package structure 1D illustrated in FIG. 1A and FIG. 1D.

FIG. 4F illustrates one or more stages of an exemplary method of forming a package structure 1D in accordance with some arrangements of the present disclosure.

In some arrangements, operations similar to those illustrated in FIGS. 4A-4D may be performed to form the structure illustrated in FIG. 4D, and then electrical contacts 81, 82, 83, 84, and 85 may be disposed in the openings 310c, 320c, 330c, 340c, and 350c. The electrical contacts 81, 82, 83, 84, and 85 may include solder elements, e.g., solder pastes. The solder pastes may be formed by printing. Next, the structure illustrated in FIG. 4F may be connected to a substrate 1000 through the electrical contacts 81, 82, 83, 84, and 85 to form the package structure 1D illustrated in FIG. 1A and FIG. 1D.

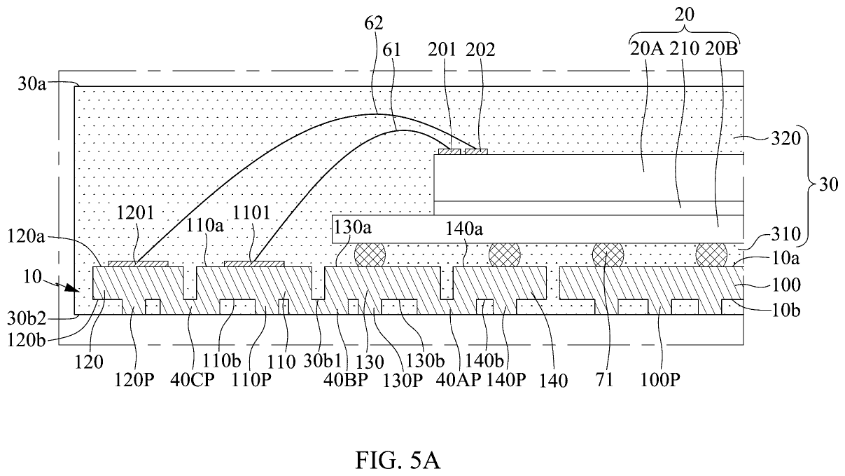

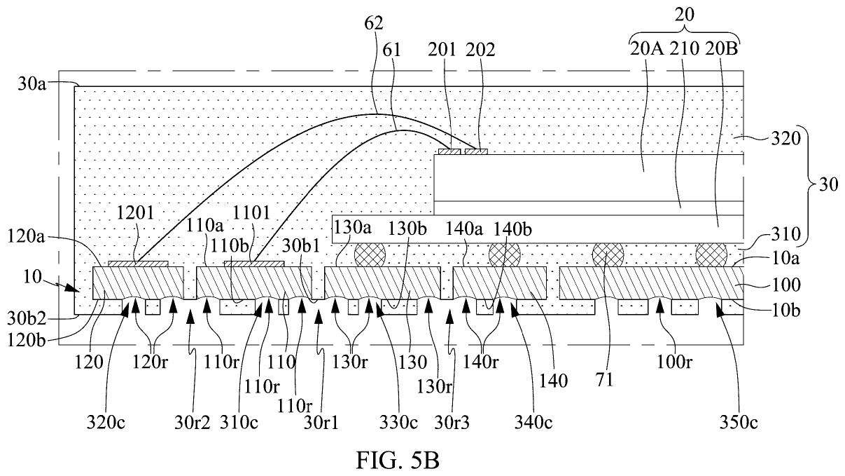

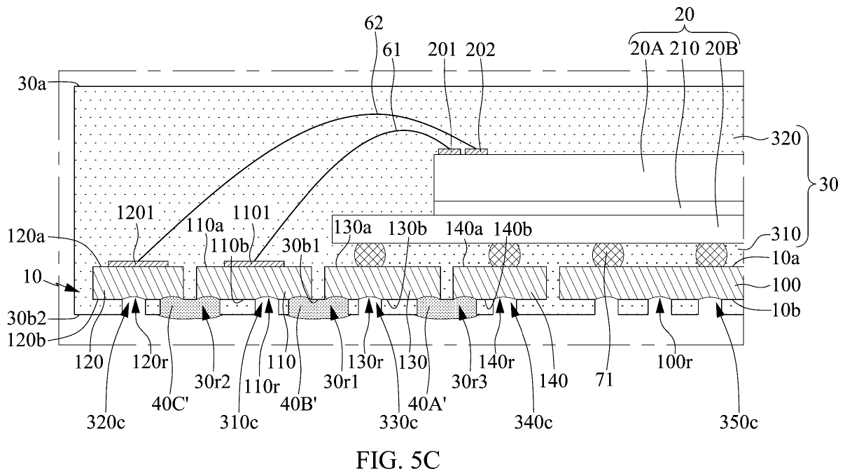

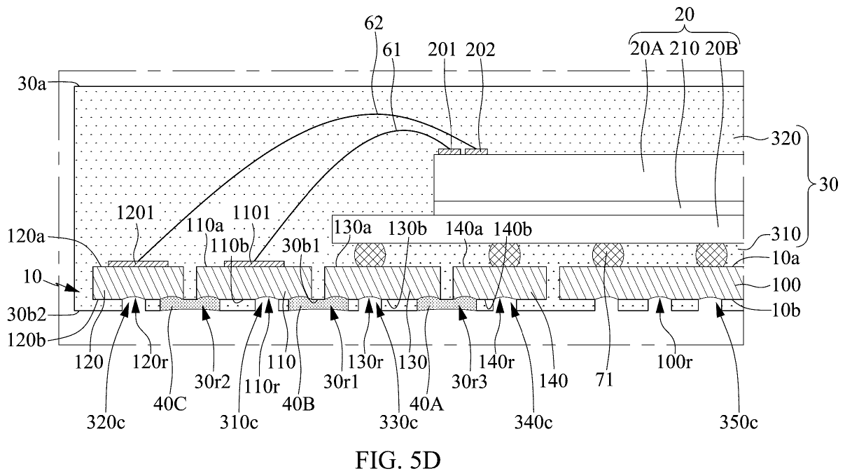

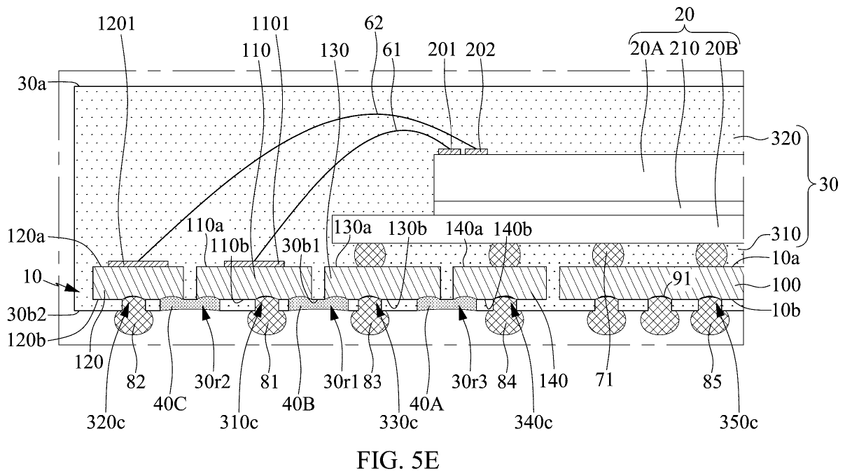

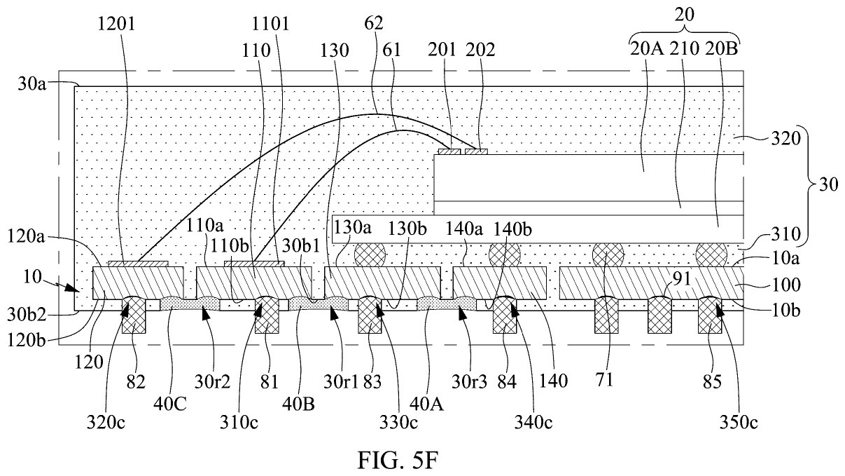

FIG. 5A to FIG. 5E illustrate various stages of an exemplary method of forming a package structure 2B in accordance with some arrangements of the present disclosure.

Referring to FIG. 5A, a leadframe 10 including a die paddle 100, leads 110, 120, 130, and 140, conductive protrusions 100P, 110P, 120P, 130P, and 140P, and connectors 40AP, 40BP, and 40CP may be provided or formed. In some arrangements, the leadframe 10 is a single piece. In some arrangements, a whole metal plate is provided, and one or more connectors are formed through half-etching from above, such as the connectors 40AP, 40BP, and 40CP. Additionally, one or more leads and conductive protrusions are formed through half-etching from below, such as the leads 110, 120, 130, and 140 and the conductive protrusions 100P, 110P, 120P, 130P, and 140P. In some arrangements, an electronic component 20 including chips 20A and 20B and an adhesive layer 210B is connected to the leadframe 10 through electrical contacts 71, conductive wires 61 and 62 are provided to electrically connect the electronic component 20 to the leadframe 10, and an encapsulant 30 is provided to encapsulate the leadframe 10 and the electronic component 20.

Referring to FIG. 5B, the conductive protrusions 100P, 110P, 120P, 130P, and 140P and the connectors 40AP, 40BP, and 40CP may be removed by etching to form openings 310c, 320c, 330c, 340c, 350c, 30r1, 30r2, and 30r3. In some arrangements, the lead 110 may include recesses 110r resulted from over-etching by the etching operation. In some arrangements, the lead 120 may include recesses 120r resulted from over-etching by the etching operation. In some arrangements, the lead 130 may include recesses 130r resulted from over-etching by the etching operation. In some arrangements, the lead 140 may include recesses 140r resulted from over-etching by the etching operation.

Referring to FIG. 5C, insulating elements 40A′, 40B′ and 40C′ may be formed in the openings 30r1, 30r2, and 30r3, respectively. In some arrangements, the insulating elements 40A′, 40B′ and 40C′ are partially formed in the recesses 110r, 120r, 130r, and 140r. In some arrangements, the insulating elements 40A′, 40B′ and 40C′ partially protrude beyond the openings 30r1, 30r2, and 30r3 and partially cover the lower surface 30b2 of the encapsulant 30. In some arrangements, the insulating elements 40A′, 40B′ and 40C′ are formed by coating.

Referring to FIG. 5D, exposed surfaces of the insulating elements 40A′, 40B′ and 40C′ may be partially removed to form insulating elements 40A, 40B, and 40C having exposed surfaces that are not protruding beyond the lower surface 30b2 of the encapsulant 30. The exposed surfaces of the insulating elements 40A′, 40B′ and 40C′ may be partially removed by polishing.

Referring to FIG. 5E, electrical contacts 81, 82, 83, 84, and 85 may be disposed in the openings 310c, 320c, 330c, 340c, and 350c. In some arrangements, the electrical contacts 81, 82, 83, 84, and 85 are partially formed in the recesses 110r, 120r, 130r, and 140r. The electrical contacts 81, 82, 83, 84, and 85 may include solder elements, e.g., solder balls. Next, the structure illustrated in FIG. 4E may be connected to a substrate 1000 through the electrical contacts 81, 82, 83, 84, and 85 to form the package structure 1C illustrated in FIG. 1A, FIG. 1C, and FIG. 2B.

FIG. 5F illustrates one or more stages of an exemplary method of forming a package structure 2B in accordance with some arrangements of the present disclosure.

In some arrangements, operations similar to those illustrated in FIGS. 5A-5D may be performed to form the structure illustrated in FIG. 5D, and then electrical contacts 81, 82, 83, 84, and 85 may be disposed in the openings 310c, 320c, 330c, 340c, and 350c. The electrical contacts 81, 82, 83, 84, and 85 may include solder elements, e.g., solder pastes. The solder pastes may be formed by printing. Next, the structure illustrated in FIG. 5F may be connected to a substrate 1000 through the electrical contacts 81, 82, 83, 84, and 85 to form the package structure 1C illustrated in FIG. 1A, FIG. 1C, and FIG. 2B.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a leadframe comprising a first lead;
an electronic component disposed over and electrically connected to an upper surface of the leadframe;
an encapsulant encapsulating the leadframe and defining a first opening exposing a first portion of a lower surface of the first lead; and
a first reflowable material disposed in the first opening, wherein the first opening is defined by curved surfaces of the encapsulant formed by etching the leadframe and having a cross-sectional profile tapering away from the first lead.

2. The package structure as claimed in claim 1, wherein the first reflowable material partially protrudes beyond the encapsulant.

3. The package structure as claimed in claim 2, wherein the encapsulant has a lower surface facing away from the leadframe, and the first reflowable material contacts a portion of the lower surface of the encapsulant.

4. The package structure as claimed in claim 1, further comprising an intermetallic compound (IMC) layer between the first reflowable material and the first lead.

5. The package structure as claimed in claim 4, wherein the IMC layer has a non-uniform thickness and directly contacts the first reflowable material and the first lead.

6. The package structure as claimed in claim 1, wherein the encapsulant comprises fillers.

7. A package structure, comprising:
a leadframe comprising a first lead;
an encapsulant encapsulating the first lead and defining a first opening and a second opening partially exposing the first lead;
a first reflowable material disposed in the first opening and comprising a portion protruding out of the first opening by a protruding distance; and
a second reflowable material disposed in the second opening, wherein a difference between a height of the first reflowable material and a height of the second reflowable material is less than the protruding distance.

8. The package structure as claimed in claim 7, wherein a width of the first reflowable material is different from a width of the second reflowable material.

9. The package structure as claimed in claim 7, further comprising:
an electronic component disposed over the leadframe;
a plurality of third reflowable materials electrically connecting the electronic component to a first surface of the leadframe; and
a plurality of the first reflowable materials and a plurality of the second reflowable materials electrically connected to a second surface opposite to the first surface of the leadframe, wherein a sum of a number of the first reflowable materials and a number of the second reflowable materials is greater than a number of the third reflowable materials.

10. The package structure as claimed in claim 7, wherein the first reflowable material and the first lead defines a curved interface convex toward the first lead.

11. The package structure as claimed in claim 10, wherein the curved interface is free from overlapping the encapsulant in a first direction substantially parallel to a surface of the first lead.

12. The package structure as claimed in claim 10, wherein a portion of the first reflowable material is between the first lead and the encapsulant.

13. The package structure as claimed in claim 7, wherein the first reflowable material partially extends into the first lead.

14. The package structure as claimed in claim 13, wherein the first reflowable material extends into the first lead by a first distance, the encapsulant further defines a third opening between the first opening and the second opening, and the package structure further comprises an insulating element disposed in the third opening and extending into the first lead by a second distance different from the first distance.

15. A package structure, comprising:
a leadframe having a first surface and a second surface opposite to the first surface;
an electronic component disposed over and electrically connected to the first surface of the leadframe;
an encapsulant encapsulating the leadframe;
a first solder ball disposed over the second surface of the leadframe; and
an insulating element configured to cover a portion of the second surface of the leadframe exposed by the encapsulant, wherein a material of the insulating element is different from a material of the encapsulant.

16. The package structure as claimed in claim 15, wherein the insulating element is disposed in a recess defined by the encapsulant and has a surface concave toward an inner portion of the insulating element.

17. The package structure as claimed in claim 16, wherein the insulating element has opposite lateral sides both connected to the encapsulant, and the surface of the insulating element comprises a first concave portion and a second concave portion concave toward the inner portion of the insulating element by different depths.

18. The package structure as claimed in claim 16, wherein a contact surface between the insulating element and the leadframe comprises a wavy surface.

19. The package structure as claimed in claim 15, wherein the first solder ball is electrically connected to the second surface of the leadframe, and the first solder ball partially overlaps the encapsulant in a direction substantially parallel to the second surface.

20. The package structure as claimed in claim 19, wherein the first solder ball comprises a reflowable material partially overlapping both the encapsulant and the insulating element.
